(19) United States
(12) Patent Application Publication
(10) Pub. No.: US 2021/0101327 A1
(43) Pub. Date: Apr. 8, 2021

(54) STRUCTURE, DECORATIVE FILM, METHOD FOR PRODUCING STRUCTURE, AND METHOD FOR PRODUCING DECORATIVE FILM

(71) Applicant: SONY CORPORATION, Tokyo (JP)

(72) Inventors: Yoshihito FUKUSHIMA, Miyagi (JP); Atsuhiro ABE, Miyagi (JP); Kazuhito SHIMODA, Kanagawa (JP)

(73) Assignee: SONY CORPORATION, Tokyo (JP)

(21) Appl. No.: 16/496,560

(22) PCT Filed: Mar. 14, 2018
(86) PCT No.: PCT/JP2018/009853

§ 371 Date: Sep. 23, 2019

(30) Foreign Application Priority Data
Mar. 31, 2017 (JP) 2017-071600

(51) Int. Cl. B29C 55/02; C23C 14/24; C23C 14/14; C23C 14/08; C23C 14/58; B29C 55/12; B29C 45/14; B29C 51/12; B29C 51/10

(52) U.S. Cl. CPC B29C 55/023; C23C 14/243; C23C 14/14; C23C 14/081; B29K 2705/02; B29C 55/12; B29C 45/14688; B29C 51/12; B29C 51/10; C23C 14/58

(57) ABSTRACT

In order to achieve the above-mentioned object, according to an embodiment of the present technology, there is provided a structure including a decorative portion and a member. The decorative portion includes a single-layered metal layer that includes fine cracks and varies in addition concentration of a predetermined element in a thickness direction of the metal layer. The member includes a decorated region to which the decorative portion is bonded.

### TECHNICAL FIELD

The present technology relates to a structure applicable, for example, to electronic apparatuses and vehicles. The present technology also relates to a decorative film, a method for producing the structure, and a method for producing the decorative film.

### BACKGROUND ART

Hitherto, a member that is capable of allowing electromagnetic waves such as millimeter waves to be transmitted therethrough despite having a metallic external appearance has been devised as a casing component for electronic apparatuses and the like. For example, Patent Literature 1 discloses an exterior component for allowing an automotive radar to be built in an emblem of an automobile. Specifically, indium is deposited on a resin film, and this film is attached to a surface layer of the emblem by an insert molding method. In such a way, an exterior component having an ornamental metallic luster and no absorption range in an electromagnetic frequency band owing to island structures of the indium can be produced (refer, for example, to paragraph [0006] of Patent Literature 1).

However, the method for forming the island structures of the indium has a problem of difficulties in making a film having a uniform thickness overall, for example, at a time when the deposition is performed over a large area. Further, the method has another problem that the island structures are easily broken due to temperature of the resin to be poured at a time of molding the casing component (refer, for example, to paragraphs [0007] and [0008] of Patent Literature 1).

In order to solve this problem, Patent Literature 1 discloses the following technology. Specifically, a sea-island structure including metal regions as islands and a non-metal region surrounding the islands as a sea is artificially formed in a regular pattern. Then, both the metal regions are insulated from each other by the non-metal region, and an area of the metal regions and an interval between adjacent ones of the metal regions are properly controlled. With this, a material that has electromagnetic-wave permeability comparable to that of a film on which the indium is deposited can be obtained (refer, for example, to paragraph [0013] of Patent Literature 1).

### CITATION LIST

### Patent Literature

Patent Literature 1: JP 2010-251899

### DISCLOSURE OF INVENTION

### Technical Problem

There have been demands for technologies for producing the member as described above, which is not only capable of allowing radio waves to be transmitted therethrough despite having a metallic luster, but also has high designability.

In view of such circumstances, the present technology has been made to achieve an object to provide a highly-designable structure capable of allowing radio waves to be transmitted therethrough despite having a metallic external appearance, a decorative film, a method for producing the structure, and a method for producing the decorative film.

### Solution to Problem

In order to achieve the above-mentioned object, according to an embodiment of the present technology, there is provided a structure including a decorative portion and a member.

The decorative portion includes a single-layered metal layer that includes fine cracks and varies in addition concentration of a predetermined element in a thickness direction of the metal layer.

The member includes a decorated region to which the decorative portion is bonded.

In this structure, the predetermined element is added to vary in the addition concentration in the thickness direction of the single-layered metal layer. With this, the above-mentioned metal layer can be made, for example, of aluminum or the like, which has a high reflectance. Further, by adjusting the addition concentration in the thickness direction, adjustment of a surface reflectance also can be performed. As a result, the highly-designable structure capable of allowing radio waves to be transmitted therethrough despite having a metallic external appearance can be provided.

The decorative portion may have a design surface.

In this case, the metal layer may have a first surface on the design surface side, and a second surface on a side opposite to a side of the first surface.

A region near the first surface may correspond to a low addition-concentration region in which the addition concentration is relatively low.

With this, a reflectance of the first surface can be increased, and a highly-designable metallic luster can be exhibited.

The low addition-concentration region may include a region in which the addition concentration is zero.

With this, a significantly high reflectance can be exhibited.

In the metal layer, at least a part region out of the region near the first surface may correspond to a high addition-concentration region in which the addition concentration is relatively high.

With this, the fine cracks can be easily formed.

In the metal layer, the addition concentration may decrease from the second surface toward the first surface.

With this, the metal layer can be easily formed.

In the metal layer, in both the region near the first surface and a region near the second surface, a percentage of a metal that is uncombined with the predetermined element may be equal to or more than a predetermined threshold.

With this, degradation of the metallic luster can be prevented, whereby high designability can be maintained.

In the metal layer, in both a region up to approximately 20 nm from the first surface and a region up to approximately 20 nm from the second surface, the percentage of the metal that is uncombined with the predetermined element may be approximately 3 atm % or more.

With this, the degradation of the metallic luster can be prevented, whereby the high designability can be maintained.

The predetermined element may be oxygen or nitrogen.

By adding the oxygen or the nitrogen, the fine cracks can be formed while maintaining the high reflectance. With this, the highly-designable structure can be provided.

The metal layer may be any of aluminum, titanium, chromium, and an alloy containing at least one of the aluminum, the titanium, or the chromium.

Use of these materials is advantageous in maintaining the high designability.

The metal layer may have a thickness of 50 nm or more and 300 nm or less.

With this, sufficient radio-wave permeability can be exhibited while maintaining the high reflectance.

The fine cracks may have a pitch within a range of 1 μm or more and 500 μm or less.

With this, the sufficient radio-wave permeability can be exhibited.

The decorative portion may include a support layer that has a tensile fracture strength lower than a tensile fracture strength of the metal layer, and that supports the metal layer.

By forming the support layer that has the tensile fracture strength lower than the tensile fracture strength of the metal layer, the fine cracks can be formed at a low orientation percentage.

The decorative portion may include a fixing layer that fixes the fine cracks.

With this, the sufficient radio-wave permeability can be exhibited.

The structure may be formed as at least a part of a casing component, a vehicle, or a construction.

By applying the present technology, the casing component, the vehicle, and the construction can each be provided to have high designability, and to be capable of allowing radio waves to be transmitted therethrough despite having a metallic external appearance.

According to another embodiment of the present technology, there is provided a decorative film including a base film and a metal layer.

The metal layer is single-layered, formed with respect to the base film, includes fine cracks, and varies in addition concentration of a predetermined element in a thickness direction of the metal layer.

According to still another embodiment of the present technology, there is provided a method for producing a structure, the method including:

forming a decorative film including a single-layered metal layer to which a predetermined element is added and in which fine cracks are formed,
the forming of the decorative film including
   forming, by deposition, the metal layer with respect to a base film in a manner that an addition concentration of the predetermined element varies in a thickness direction of the metal layer, and
   forming the fine cracks in the metal layer by orienting the base film;
forming a transfer film by bonding a carrier film to the decorative film; and
forming a molded component in a manner that the decorative film is transferred from the transfer film by an in-mold molding method, a hot stamping method, or a vacuum molding method.

In this producing method, the single-layered metal layer to which the predetermined element is added is formed with respect to the base film in the manner that the addition concentration varies in the thickness direction. Then, the fine cracks are formed by orienting the base film. With this, for example, the aluminum or the like, which has a high reflectance, can be used as the metal layer. Further, by adjusting the addition concentration in the thickness direction, the adjustment of the surface reflectance also can be performed. As a result, the highly-designable structure capable of allowing radio waves to be transmitted therethrough despite having a metallic external appearance can be provided.

In another method for producing a structure according to the still other embodiment of the present technology, a transfer film including the metal layer to which the predetermined element is added and in which the fine cracks are formed is formed.

Further, the molded component is formed in a manner that the metal layer peeled off from the base film is transferred by the in-mold molding method, the hot stamping method, or the vacuum molding method.

In still another method for producing a structure according to the still other embodiment of the present technology,

the molded component is formed integrally with the decorative film by an insert molding method.

The forming of the fine cracks may include biaxially orienting the base film at an orientation percentage of 2% or less in each axial direction.

Since the predetermined element is added, the fine cracks can be formed at the low orientation percentage.

A method for producing a decorative film according to yet another embodiment of the present technology includes:

forming, with respect to a base film by deposition, a single-layered metal layer to which a predetermined element is added in a manner that an addition concentration of the predetermined element varies in a thickness direction of the metal layer; and

forming fine cracks in the metal layer by orienting the base film.

### Advantageous Effects of Invention

As described above, according to the present technology, the highly-designable structure capable of allowing radio waves to be transmitted therethrough despite having a metallic external appearance can be provided. Note that, the advantages disclosed herein are not necessarily limited to those described hereinabove, and not only the advantages described hereinabove but also those described hereinbelow can be obtained.

### BRIEF DESCRIPTION OF DRAWINGS

FIG. 1 A schematic view illustrating a configuration example of a mobile terminal as an electronic apparatus according to an embodiment.

FIG. 2 A schematic cross-sectional view illustrating a configuration example of a metal decorative portion illustrated in FIG. 1.

FIG. 3 A photograph of a surface condition of a metal layer on an enlarged scale through a microscope.

FIG. 4 An explanatory view showing an addition concentration of oxygen in a thickness direction of the metal layer.

FIG. 5 A schematic view illustrating a configuration example of a vacuum deposition apparatus.

FIG. 6 A schematic view illustrating a configuration example of a biaxial orientation apparatus.

FIG. 7 A schematic cross-sectional view illustrating another configuration example of the metal decorative portion.

FIG. 8 An explanatory view showing an addition concentration of the oxygen in a thickness direction of a metal layer illustrated in FIG. 7.

FIG. 9 A table showing percentages of aluminum in the metal layers 20 and optical characteristics after high-temperature and high-humidity tests of samples 1 to 4 each prepared as a decorative film.

FIG. 10 A graph showing a composition distribution in a thickness direction of the metal layer in the sample 1.

FIG. 11 A graph showing a composition distribution in a thickness direction of the metal layer in the sample 2.

FIG. 12 A graph showing a composition distribution in a thickness direction of the metal layer in the sample 3.

FIG. 13 A graph showing an example of an X-ray photoelectron spectroscopy analysis of a narrow-scan spectrum.

FIG. 14 A photograph of a cross-sectional TEM image of the metal layer in the sample 3.

FIG. 15 An explanatory schematic view illustrating an in-mold molding method.

FIG. 16 An explanatory schematic view illustrating an insert molding method.

FIG. 17 A schematic view illustrating a configuration example of a transfer film including a base film and a metal layer.

FIG. 18 A cross-sectional view illustrating a configuration example of a luster film according to another embodiment.

FIG. 19 A view showing a relationship between a thickness of a coating layer formed as a support layer and a pitch of fine cracks.

FIG. 20 An explanatory view showing another configuration example of the metal layer to which a predetermined element is added.

FIG. 21 An explanatory view showing still another configuration example of the metal layer to which the predetermined element is added.

FIG. 22 An explanatory view illustrating yet another configuration example of the metal layer to which the predetermined element is added.

FIG. 23 A schematic view illustrating another configuration example of the decorative film.

### MODE(S) FOR CARRYING OUT THE INVENTION

Now, embodiments according to the present technology are described with reference to the drawings.

[Configuration of Electronic Apparatus]

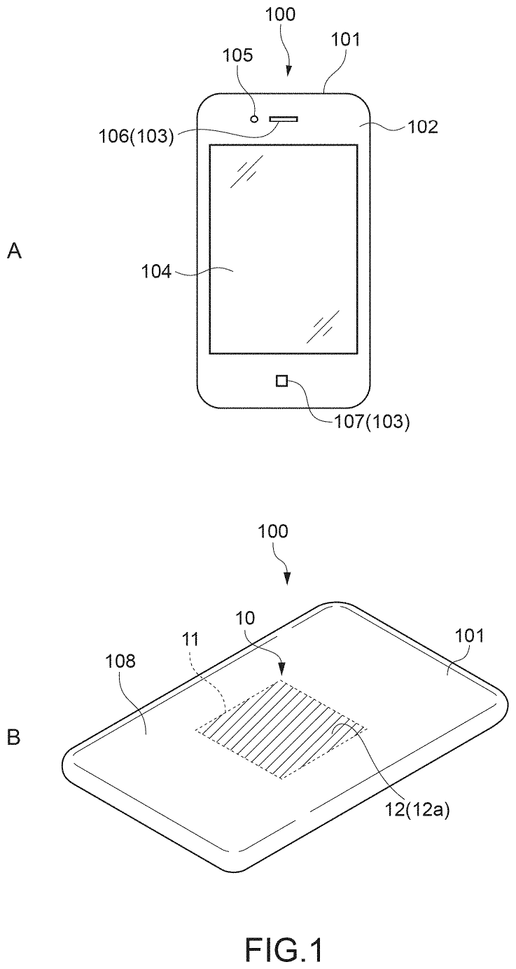

FIG. 1 is a schematic view illustrating a configuration example of a mobile terminal as an electronic apparatus according to one of the embodiments of the present technology. A of FIG. 1 is a front view illustrating a front side of a mobile terminal 100, and B of FIG. 1 is a perspective view illustrating a rear side of the mobile terminal 100.

The mobile terminal 100 includes a casing portion 101 and electronic components (not shown) that are housed in the casing portion 101. As illustrated in A of FIG. 1, a front-surface portion 102 being a front-surface side of the casing portion 101 is provided with a communication unit 103, a touchscreen 104, and a front-facing camera 105. The communication unit 103, which is provided for allowing talking with another party over the phone, includes a speaker unit 106 and an audio input unit 107. The speaker unit 106 outputs voice of the other party, and the audio input unit 107 allows voice of a user to be transmitted to the other party.

The touchscreen 104 displays various images and GUIs (Graphical User Interfaces). The user can browse still images and moving images via the touchscreen 104. Further, the user inputs various touch operations via the touchscreen 104. The front-facing camera 105 is used in capturing, for example, the face of the user. Specific configurations of these devices are not limited.

As illustrated in B of FIG. 1, a rear-surface portion 108 being a rear side of the casing portion 101 is provided with a metal decorative portion 10 decorated to have a metallic external appearance. The metal decorative portion 10 is capable of allowing radio waves to be transmitted therethrough despite having the metallic external appearance.

As described in detail below, a decorated region 11 is formed in a predetermined region in the rear-surface portion 108. The metal decorative portion 10 is formed by bonding a decorative film 12 to the decorated region 11. Thus, the decorated region 11 corresponds to a region in which the metal decorative portion 10 is formed.

In this embodiment, the decorative film 12 corresponds to a “decorative portion.” Further, the casing portion 101 in which the decorated region 11 is formed corresponds to a “member.” The casing portion 101 including the decorated region 11, and the decorative film 12 that is bonded to the decorated region 11 allow a structure according to the present technology to be constituted as a casing component. Note that, the structure according to the present technology may be used as a part of the casing component.

In the example illustrated in B of FIG. 1, the metal decorative portion 10 is partially formed substantially at a center of the rear-surface portion 108. A position at which the metal decorative portion 10 is formed is not limited, and may be set as appropriate. For example, the metal decorative portion 10 may be formed all over the rear-surface portion 108. With this, an entirety of the rear-surface portion 108 is allowed to uniformly have the metallic external appearance.

Also by making other parts around the metal decorative portion 10 have substantially the same external appearance as that of the metal decorative portion 10, the entirety of the rear-surface portion 108 is allowed to uniformly have the metallic external appearance. Alternatively, the parts out of the metal decorative portion 10 may have other external appearances such as a wood-grain pattern. With this, designability can be increased. There are no problems even when, for example, a position and a size of the metal decorative portion 10, and the external appearance of the other parts are set as appropriate such that designability that the user desires is exhibited.

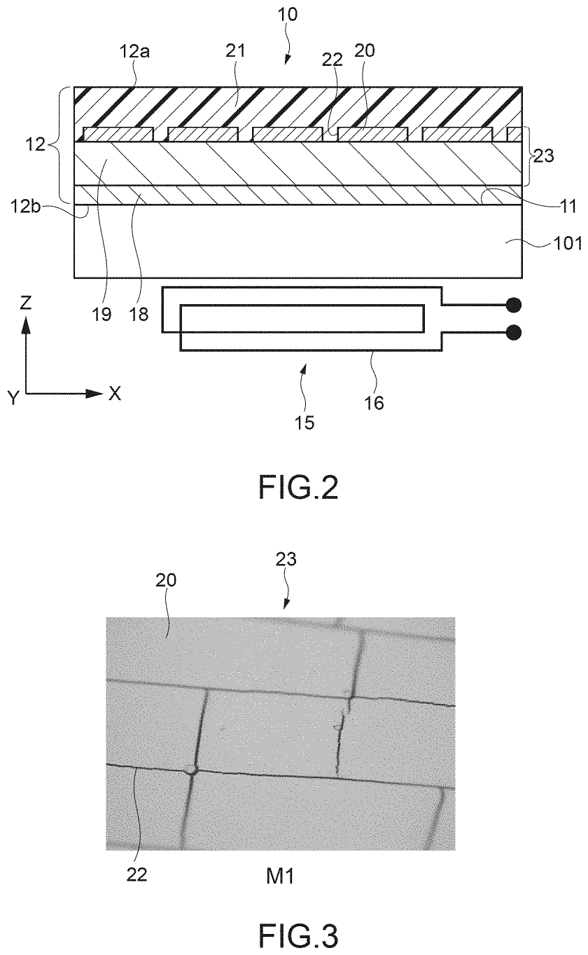

The decorative film 12 that is bonded to the decorated region 11 has a design surface 12a. The design surface 12a, which is a surface that the user of the mobile terminal 100 can visually recognize, is one of constituents of the external appearance (design) of the casing portion 101. In this embodiment, a surface that is exposed on an outer surface side of the rear-surface portion 108 corresponds to the design surface 12a of the decorative film 12. In other words, a surface on a side opposite to that of a bonding surface 12b (refer to FIG. 2) that is bonded to the decorated region 11 corresponds to the design surface 12a.

In this embodiment, as the electronic components that are housed in the casing portion 101, an antenna unit 15 (refer to FIG. 2) capable of allowing communication, for example, with an external reader/writer via the radio waves is housed. The antenna unit 15 includes, for example, a base substrate (not shown), an antenna coil 16 formed on the base substrate (refer to FIG. 2), a signal-processing circuit unit (not shown) that is electrically connected to the antenna coil 16, and the like. The specific configuration of the antenna unit 15 is not limited. Note that, as the electronic components to be housed in the casing portion 101, various electronic components such as an IC chip and a capacitor may be housed.

FIG. 2 is a schematic cross-sectional view illustrating a configuration example of the metal decorative portion 10. As described above, the metal decorative portion 10 includes the decorated region 11 formed in the region corresponding, for example, to a position of the antenna unit 15, and the decorative film 12 that is bonded to the decorated region 11.

The decorative film 12 includes an adhesive layer 18, a base film 19, a metal layer 20, and a sealing resin 21. The adhesive layer 18 is a layer for bonding the decorative film 12 to the decorated region 11. The adhesive layer 18 is formed by applying an adhesive material to a surface of the base film 19, the surface being on a side opposite to that of a surface on which the metal layer 20 is formed. Types, applying methods, and the like of the adhesive material are not limited. A surface of the adhesive layer 18, the surface being bonded to the decorated region 11, corresponds to the bonding surface 12b of the decorative film 12.

The base film 19 is made of a material having orientability, and a resin film is typically used as the base film 19. As the material of the base film 19, for example, PET (polyethylene terephthalate), PC (polycarbonate), PMMA (polymethylmethacrylate), PP (polypropylene), or the like is used. Other materials may be used.

Note that, since the base film 19 is a layer in contact with the metal, if, for example, a vinyl-chloride-based material is used, free chlorine can promote corrosion of the metal. Thus, by selecting non-vinyl-chloride-based materials as that of the base film 19, the corrosion of the metal can be prevented. As a matter of course, the material is not limited thereto.

The metal layer 20 is formed to make the decorated region 11 have the metallic external appearance. In the metal layer 20, which is a layer formed with respect to the base film 19 by vacuum deposition, a large number of fine cracks (hereinafter, abbreviated as “fine cracks”) 22 are formed.

These fine cracks 22 form a plurality of discontinuous surfaces in the metal layer 20, and a sheet resistance value is increased to provide substantial insulation. Thus, generation of an eddy current at a time when the radio waves are applied to the casing portion 101 can be sufficiently suppressed. As a result, a decrease in electromagnetic energy due to eddy-current loss can be sufficiently suppressed, and high radio-wave permeability is exhibited.

A film thickness of the metal layer 20 is set within a range of, for example, 50 nm or more and 300 nm or less. When the film thickness is excessively small, light beams transmit therethrough to cause a decrease in reflectance in a visible-light band. When the film thickness is excessively large, a surface shape is liable to be coarse to cause the decrease in the reflectance. Further, as the film thickness becomes smaller, an amount of the decrease in the reflectance after a high-temperature and high-humidity test (for example, 75° C. and 90% RH for 48 H) increases. Note that, RH is an abbreviation of “Relative Humidity.”

By setting the film thickness within the above-mentioned range in consideration of these factors, a radio-wave transmitting surface maintaining a high reflectance was successfully formed. Specifically, by setting the film thickness within a range of 50 nm or more and 150 nm or less, a high reflectance was sufficiently maintained, and the high radio-wave permeability was exhibited. As a matter of course, the film thickness of the metal layer 20 is not limited to these ranges, and may be set as appropriate as long as desired characteristics are exhibited. Alternatively, for example, a specific optimum-numerical range may be set within the range of 50 nm or more and 300 nm or less.

The sealing resin 21, which is made of a transparent material, functions as a protective layer (hard coating layer) that protects the base film 19 and the metal layer 20. The sealing resin 21 is formed, for example, by applying an UV-curable resin, a thermosetting resin, a two-part curable resin, or the like. By forming the sealing resin 21, for example, smoothing, antifouling, antipeeling, scratch proofing, and the like are achieved. Note that, as the protective member, coating with an acrylic resin or the like may be performed. The selection of the non-vinyl-chloride-based materials as the sealing resin 21 is advantageous in preventing the corrosion of the metal.

Further, the sealing resin 21 also has a function to fix and prevent the fine cracks 22 in the metal layer 20 from closing. In other words, the sealing resin 21 functions also as a fixing layer. With this, the sufficient radio-wave permeability can be exhibited, and the radio-wave permeability can be maintained for a long time period. Note that, a layer that functions as the protective layer and a layer that functions as the fixing layer, which are be configured separately from each other, may be formed as a cover layer having a bilayer structure on the metal layer 20.

A surface of the sealing resin 21, that is, a surface on a side opposite to a side that covers the metal layer 20 corresponds to the design surface 12a of the decorative film 12. Note that, for example, a printed layer may be formed on the surface of the sealing resin 21 (design surface 12a) or the lower surface of the sealing resin 21. With this, the designability can be increased.

In this embodiment, at a time when the decorative film 12 is formed, first, a luster film 23 including the base film 19 and the metal layer 20 is formed. Then, the adhesive layer 18 and sealing resin 21 are formed with respect to the luster film 23. Note that, an order of forming these layers is not limited thereto. Further, depending, for example, on a molding condition of the casing portion 101, the adhesive layer 18 and the sealing resin 21 may be omitted. In this case, the luster film 23 is bonded as the decorative film according to the present technology to the decorated region 11.

FIG. 3 is a photograph of a surface condition of the metal layer 20 of the luster film 23 on an enlarged scale through a microscope. In this embodiment, an aluminum layer to which oxygen is added as a predetermined element is formed as the metal layer 20 on the base film 19. Then, the base film 19 is biaxially oriented under a condition of an orientation percentage of 2% (amount of orientation with respect to an original size), and of substrate heating at 130° C. With this, the fine cracks 22 are formed.

As depicted in a photograph M1, in the metal layer 20, the fine cracks 22 are formed in a mesh-like pattern along biaxial directions. In other words, the fine cracks 22 are formed along two directions substantially orthogonal to each other in a manner that the fine cracks 22 intersect with each other. A pitch (crack interval) of the fine cracks 22 in each of the directions is set, for example, within a range of 1 μm or more and 500 μm or less.

Specifically, when the pitch is excessively small, light beams to be reflected by the surfaces of the metal layer 20 are scattered, and an area of voids (gaps) having light permeability relatively increases. Thus, the reflectance decreases. Meanwhile, when the pitch is excessively large, the radio-wave permeability decreases. By setting the pitch within the range of 1 μm or more and 500 μm or less, the radio-wave permeability can be exhibited while maintaining the high reflectance. For example, electromagnetic waves at 2.45 GHz of WiFi and Bluetooth (trademarks) (wavelength of approximately 12.2 cm) can be sufficiently transmitted.

As a matter of course, the pitch of the fine cracks 22 is not limited to this range, and may be set as appropriate as long as desired characteristics are exhibited. For example, by setting the pitch within a range of 50 μm or more and 200 μm or less, a high reflectance and the high radio-wave permeability were sufficiently exhibited. Alternatively, for example, a specific optimum-numerical range may be set within the range of 1 μm or more and 500 μm or less.

Evaluation of the sheet resistance of the metal layer 20 in the photograph M1 with use of a four-probe resistor demonstrated insulating properties. Further, measurement of the surface reflectance in the visible-light band (400 nm to 700 nm) with use of a spectrophotometer (U-4100 “produced by Hitachi, Ltd.”) demonstrated a value of 70% or more. In other words, the metal layer 20 which has a surface with the high reflectance, a metallic luster, and the sufficient radio-wave permeability was successfully formed.

Note that, when the protective layer such as the sealing resin 21 or the hard coating layer is formed, the surface reflectance decreases by approximately 5%. In consideration of this phenomenon, by using the decorative film 12 according to the present technology, the value of the surface reflectance can be increased to as high as 65% or more under the state in which the protective layer is formed.

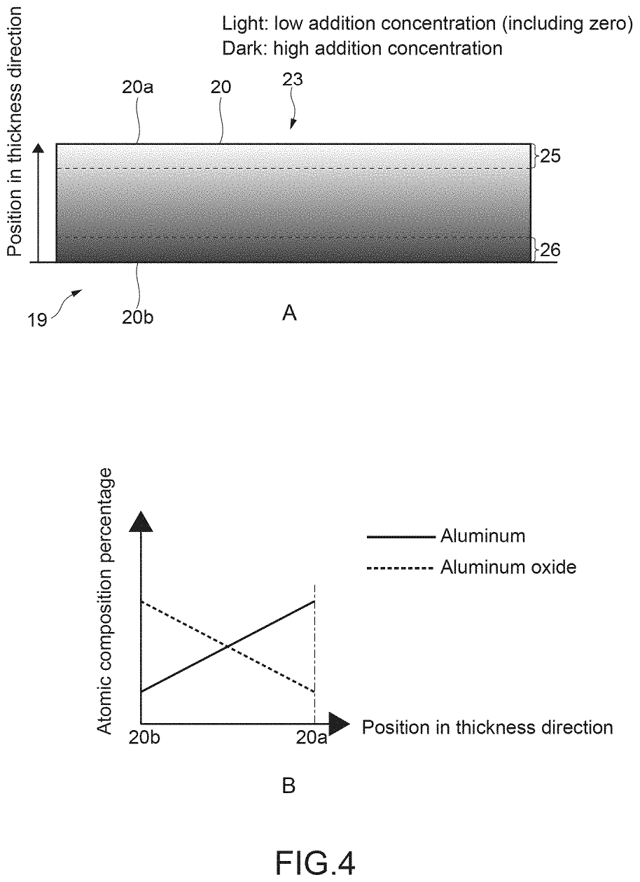

FIG. 4 is an explanatory view showing an addition concentration of the oxygen in a thickness direction of the metal layer 20. A of FIG. 4 is a schematic view illustrating the metal layer 20 in its cross-section, which represents the addition concentration of the oxygen in grayscale. The higher the addition concentration becomes, the darker a tone in which a region corresponding to the higher addition concentration is represented becomes. The lower the addition concentration becomes, the lighter a tone in which a region corresponding to the lower addition concentration is represented becomes. Note that, in the present disclosure, the state in which the addition concentration is low includes a state in which the addition concentration is zero. B of FIG. 4 is a schematic graph showing an atomic composition percentage between aluminum (metallic aluminum) and aluminum oxide at positions in the thickness direction of the metal layer 20.

As illustrated in A of FIG. 4, the metal layer 20 is single-layered, and has a first surface 20a and a second surface 20b. The first surface 20a, which is a surface on the design surface 12a side of the decorative film 12 illustrated in FIG. 2, is visually recognized by the user through the transparent sealing resin 21. The second surface 20b, which is a surface on a side opposite to that of the first surface 20a, is connected to the base film 19.

The metal layer 20 is formed to vary in the addition concentration of the oxygen. In this embodiment, the metal layer 20 is formed in a manner that the addition concentration of the oxygen decreases from the second surface 20b toward the first surface 20a in the thickness direction of the metal layer 20. In other words, in this embodiment, the oxygen is added such that the addition concentration of the oxygen has a gradient along the thickness direction. Note that, the addition concentration need not necessarily be consecutively vary, and may be vary in a stepwise manner.

As shown in FIG. 4, a first near region 25 being a region near the first surface 20a in the thickness direction corresponds to a low addition-concentration region in which the addition concentration of the oxygen is relatively low. A second near region 26 being a region near the second surface 20b corresponds to a high addition-concentration region in which the addition concentration of the oxygen is relatively high.

The “near region” refers to a region in a range near each of the surfaces with respect to an entirety of the film thickness, and, for example, a specific thickness from each of the surfaces is not limited. Specifically, an inward region from each of the surfaces, which corresponds to a thickness at a predetermined percentage of the entirety of the thickness of the metal layer 20, may be defined as the “near region.” More specifically, a region corresponding to a thickness of, for example, ¼, ⅕, or ⅙ of the entirety of the thickness may be defined as the “near region.” As a matter of course, the thickness of the “near region” is not limited thereto, and a region corresponding to a predetermined thickness from each of the surfaces may be defined as the “near region.” The “near region” can be paraphrased, for example, as a region in a vicinity of corresponding one of the surfaces.

Further, the low addition-concentration region includes a region in which the addition concentration is zero. Thus, for example, a case where the oxygen is not added to a part region in the first near region 25, a case where the oxygen is not added to an entirety of the first near region, and the like correspond to the case where the first near region corresponds to the low addition-concentration region.

As shown in B of FIG. 4, a percentage of the aluminum that is uncombined with the oxygen increases from the second surface 20b toward the first surface 20a. Meanwhile, a percentage of the aluminum oxide that is generated by being combined with the oxygen decreases from the second surface 20b toward the first surface 20a.

When the metal layer 20 is formed by adding the oxygen in such a way, the fine cracks 22 can be easily formed by orienting the base film 19. This is probably because the high addition-concentration region in which the addition concentration of the oxygen is relatively high corresponds to a region having low tensile-fracture strength in the film, and because the fine cracks 22 start to be formed from this region.

With this, the metal layer 20 can be made, for example, of the aluminum or the like, which has low hardness and difficulties in forming cracks even by being oriented. The aluminum has a high reflectance in the visible-light band, and hence the design surface 12a (first surface 20a) is enabled to exhibit the high reflectance. As a result, a highly-designable metallic luster can be exhibited.

Further, by reducing the addition concentration in the first near region 25 on the first surface 20a side such that the first near region 25 is used as the low addition-concentration region, a percentage of the aluminum in the first near region 25 is increased. With this, the reflectance of the design surface 12a can be further increased. As a result, the casing portion 101 can be formed to have the high designability, and to be capable of allowing radio waves to be transmitted therethrough despite having the metallic external appearance.

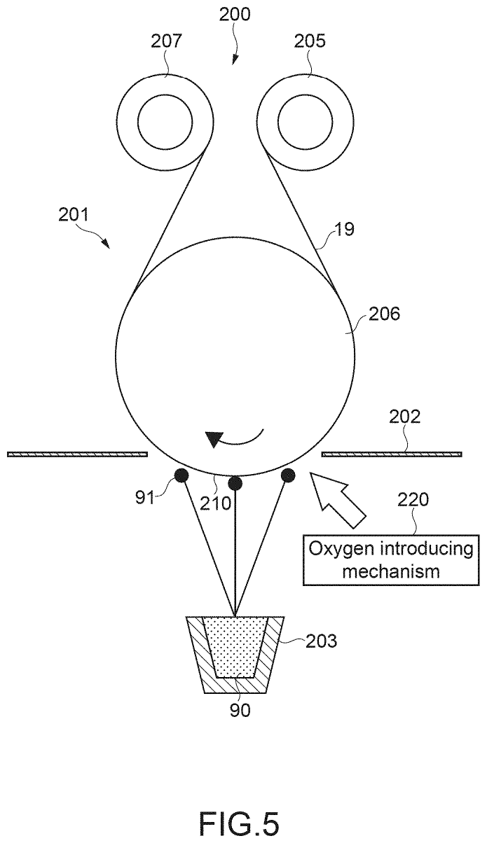

FIG. 5 is a schematic view illustrating a configuration example of a vacuum deposition apparatus. A vacuum deposition apparatus 200 includes a film transport mechanism 201, a partition wall 202, a crucible 203, a heat source (not shown), and an oxygen introducing mechanism 220 that are arranged in a vacuum chamber (not shown).

The film transport mechanism 201 includes an unwind roll 205, a rotating drum 206, and a take-up roll 207. The base film 19 is transported from the unwind roll 205 toward the take-up roll 207 along a peripheral surface of the rotating drum 206.

The crucible 203 is arranged at a position that faces the rotating drum 206. The crucible 203 contains aluminum 90 as a metal material that forms the metal layer 20. A region of the rotating drum 206, which faces the crucible 203, corresponds to a deposition region 210. The partition wall 202 restricts fine particles 91 of the aluminum 90, which are scattered at angles toward regions out of the deposition region 210. The oxygen introducing mechanism 220 is arranged on an upstream side (unwind roll 205 side) with respect to the deposition region 210. An arbitrary apparatus may be used as the oxygen introducing mechanism 220.

The rotating drum 206 is sufficiently cooled, and in this state, the base film 19 is transported. The oxygen introducing mechanism 220 blows the oxygen onto the base film 19. The oxygen to be supplied by the oxygen introducing mechanism 220 corresponds to a gas containing the predetermined element. An introduction rate (flow rate: sccm) of the oxygen is not limited, and an arbitrary flow rate may be set.

In synchronization with the supply of the oxygen, the aluminum 90 in the crucible 203 is heated by the heat source such as a heater, laser, an electron gun, or the like (none of which is shown). With this, vapor containing the fine particles 91 is generated from the crucible 203. The fine particles 91 of the aluminum 90, which are contained in the vapor, are deposited on the base film 19 that travels through the deposition region 210. With this, an aluminum layer to which the oxygen has been added is deposited as the metal layer 20 on the base film 19.

Since the oxygen introducing mechanism 220 is arranged on the upstream side with respect to the deposition region 210, an amount of the oxygen to be added to a part of the metal layer 20 increases, the part being formed on the base film 19 on the upstream side. Meanwhile, an amount of the oxygen to be added to another part of the metal layer 20 decreases, the other part being formed on a downstream side. In other words, a deposition start surface corresponds to a surface having a highest addition concentration, and a deposition end surface corresponds to a surface having a lowest addition concentration.

In such a way, by adjusting the position of the oxygen introducing mechanism 220, the metal layer 20 shown in FIG. 4, in which the addition concentration of the oxygen decreases from the second surface 20b toward the first surface 20a, can be easily formed. Note that, the second surface 20b of the metal layer 20 corresponds to the deposition start surface, and the first surface 20a of the same corresponds to the deposition end surface.

In this embodiment, the vacuum deposition can be continuously performed by the roll-to-roll system. Thus, a significant cost reduction and a significant productivity increase can be achieved. As a matter of course, the present technology is applicable also to a case where a vacuum deposition apparatus of a batch type is used.

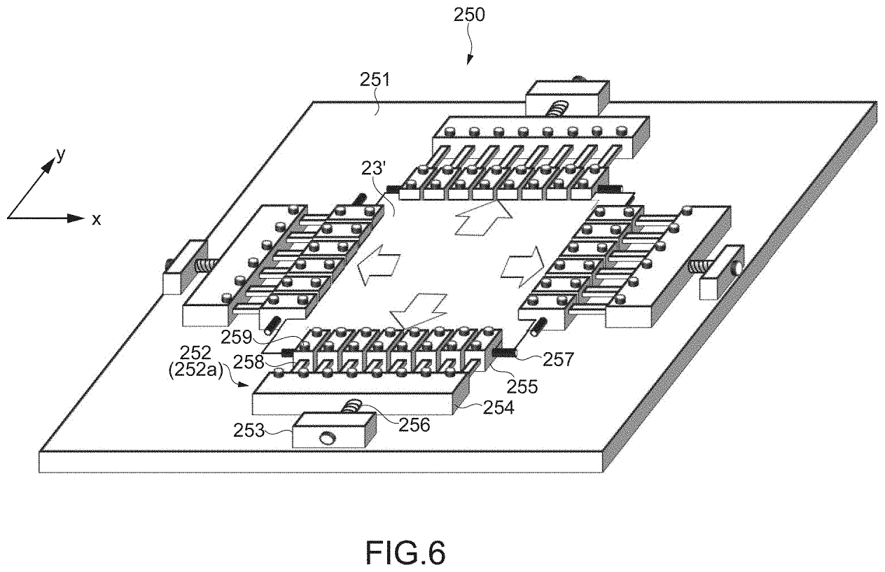

FIG. 6 is a schematic view illustrating a configuration example of a biaxial orientation apparatus. A biaxial orientation apparatus 250 includes a base member 251 and four orienting mechanisms 252 that are arranged on the base member 251 and have substantially the same configuration as each other. Two of the four orienting mechanisms 252 are arranged on one of two axes orthogonal to each other (x-axis and y-axis), and other two are arranged on another one of the two axes respectively so as to face each other respectively on the axes. Now, description is made with reference to an orienting mechanism 252a that orients a luster film 23′ in a direction opposite to an arrow of the y-axis direction.

The orienting mechanism 252a includes a fixed block 253, a movable block 254, and a plurality of clips 255. The fixed block 253 is fixed to the base member 251. An orienting screw 256 that extends in an orientation direction (y-direction) penetrates the fixed block 253.

The movable block 254 is arranged to be movable on the base member 251. The movable block 254 is connected to the orienting screw 256 that penetrates the fixed block 253. Thus, by operating the orienting screw 256, the movable block 254 can be moved in the y-direction.

The plurality of clips 255 is arranged along the direction (x-direction) orthogonal to the orientation direction. A slide shaft 257 that extends in the x-direction penetrates all of the plurality of clips 255. A position in the x-direction of each of the clips 255 can be changed along the slide shaft 257. The plurality of clips 255 and the movable block 254 are coupled to each other respectively with coupling links 258 and coupling pins 259.

By an amount of the operation of the orienting screw 256, the orientation percentage is controlled. Further, also by setting, for example, the number or the positions of the plurality of clips 255, and a length of the coupling links 258 as appropriate, the orientation percentage can be controlled. Note that, the configuration of the biaxial orientation apparatus 250 is not limited. Although the biaxial orientation apparatus 250 according to this embodiment biaxially orients a film being a full-cut sheet, the biaxial orientation can be continuously performed with rolls. For example, the continuous biaxial orientation can be performed by applying tension in a travelling direction between the rolls, and by applying tension orthogonal to the travelling direction by the clips 255 that are provided between the rolls and moved in synchronization with the travelling.

The luster film 23′ after the vacuum deposition is arranged on the base member 201, and the plurality of clips 255 of the orienting mechanism 252 is attached to each of the four sides. The luster film 23′ is heated by a temperature-controlled heating lamp or a temperature-controlled hot blast (none of which is shown), and in this state, the four orienting screws 256 are operated. In such a way, the biaxial orientation is performed. In this embodiment, the base film 19 is biaxially oriented under a condition of an orientation percentage of 2% and substrate heating at 130° C. in each of the axis directions. With this, as depicted in FIG. 3, the fine cracks 22 are formed in the mesh-like pattern along the directions (biaxial directions) orthogonal to the orientation directions.

When the orientation percentage is excessively low, the fine cracks 22 are improperly formed, and the metal layer 20 has conductivity. In this case, by influence of, for example, the eddy current, the sufficient radio-wave permeability cannot be exhibited. Meanwhile, when the orientation percentage is excessively high, damage to the base film 19 after the orientation increases. As a result, at the time of bonding the decorative film 12 to the decorated region 11, air entrainment, creases, or the like may occur to reduce yields. Further, the base film 19 itself or the metal layer 20 itself may be deformed to degrade the designability of the metal decorative portion 10. These problems may occur also when the metal layer 20 is peeled off from the base film 19 and transferred.

In the luster film 23 according to this embodiment, the fine cracks 22 can be properly formed at the orientation percentage of as low as 2% or less in each of the axis directions. With this, the damage to the base film 19 can be sufficiently prevented, and the yields can be increased. Further, the designability of the metal decorative portion 10 to which the decorative film 12 is bonded can be maintained to be high. As a matter of course, the orientation percentage may be set as appropriate, and an orientation percentage of 2% or more may be set unless the problems as described above occur.

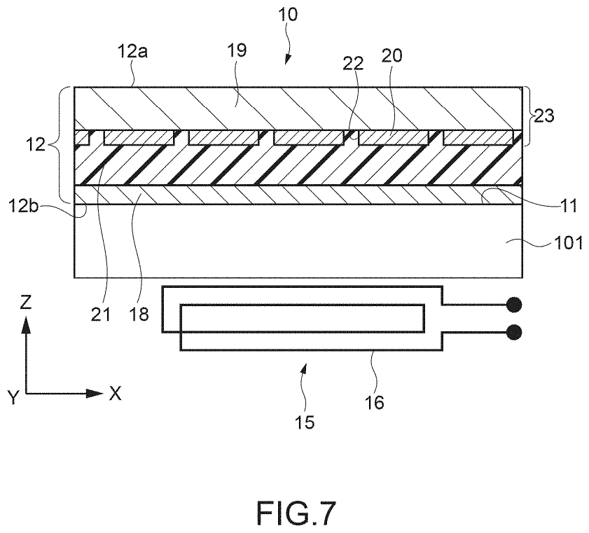

FIG. 7 is a schematic cross-sectional view illustrating another configuration example of the metal decorative portion. In the example illustrated in FIG. 7, the adhesive layer 18 is formed on the sealing resin 21 that covers the metal layer 20, and the sealing resin 21 side is bonded to the decorated region 11 of the casing portion 101. Thus, the surface of the base film 19, which is on the side opposite to that of the surface on which the metal layer 20 is formed, corresponds to the design surface 12a of the decorative film 12. In this case, the base film 19 to be used may be transparent, and the sealing resin 21 to be used may be opaque. In other words, the sealing resin 21 to be used may be colored in arbitrary colors. With this, the designability can be increased.

Note that, the protective layer may be formed on the base film 19, or the base film 19 may have a function as the protective layer. Alternatively, a layer having functions of all of the protective layer that protects the metal layer 20, the fixing layer that prevents the fine cracks 22 from closing, and the bonding layer for bonding the decorative film 12 to the decorated region 11 may be formed to cover the metal layer 20.

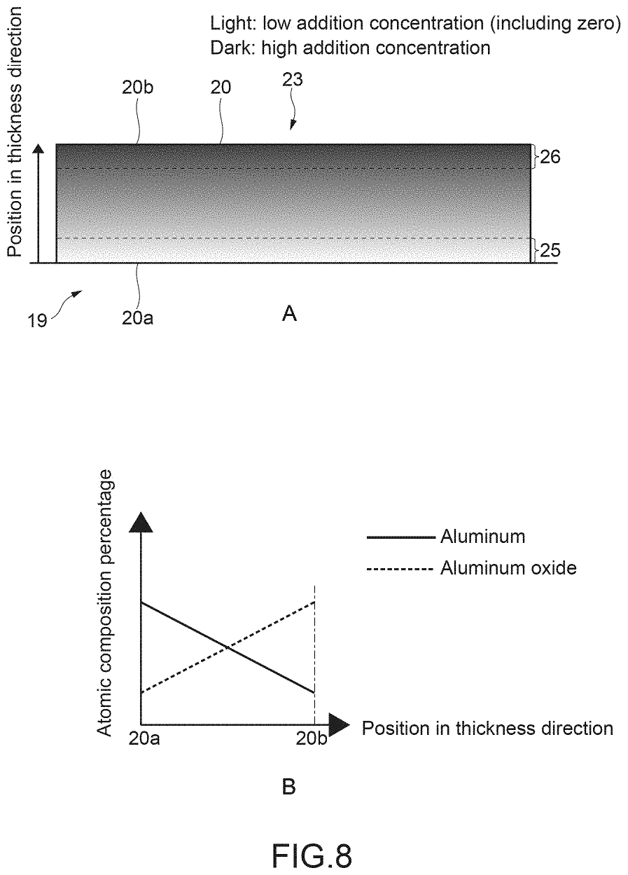

FIG. 8 is an explanatory view showing an addition concentration of oxygen in a thickness direction of the metal layer 20 illustrated in FIG. 7. Since the base film 19 side corresponds to the design surface 12a, a surface (deposition start surface) that is connected to the base film 19 corresponds to the first surface 20a, and a surface on an opposite side (deposition end surface) corresponds to the second surface 20b. Also in this case, the addition concentration of the oxygen can be reduced from the second surface 20b toward the first surface 20a. With this, the reflectance in the visible-light band can be increased in the design surface 12a (first surface 20a). As a result, the highly-designable metallic luster can be exhibited.

In the vacuum deposition apparatus 200 illustrated in FIG. 5, by arranging the oxygen introducing mechanism 220 on the downstream side (take-up roll 207 side) with respect to the deposition region 210, the metal layer 20 having a distribution of the addition concentration shown in FIG. 8 can be easily formed. As a matter of course, other methods may be employed.

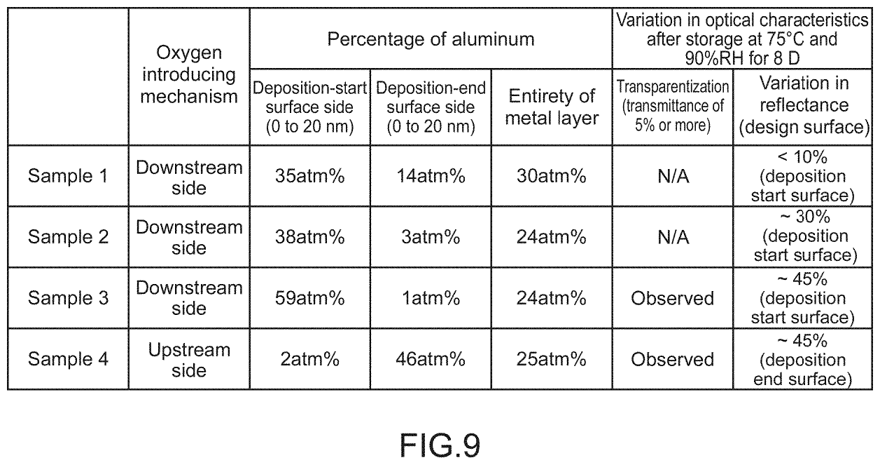

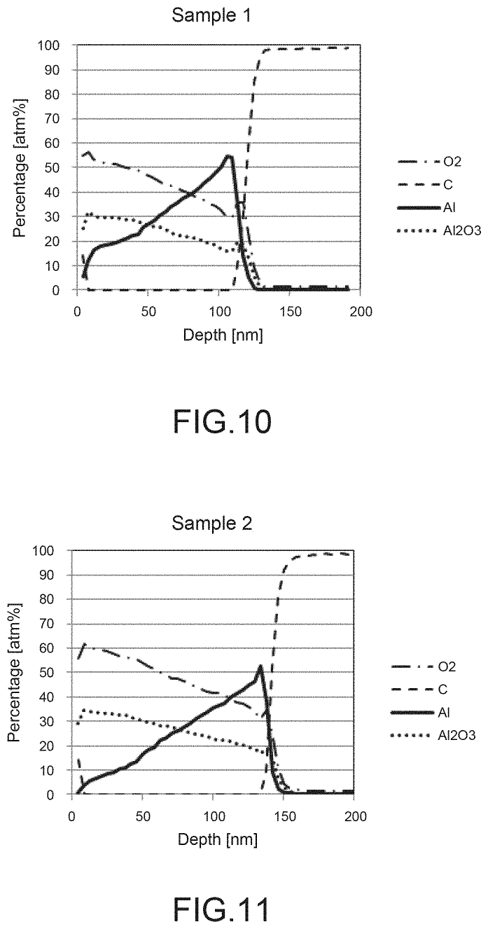

FIG. 9 is a table showing the percentages of the aluminum in the metal layers 20 and optical characteristics after the high-temperature and high-humidity tests of samples 1 to 4 each prepared as the decorative film 12. FIG. 10 to FIG. 12 are graphs respectively showing composition distributions in the thickness direction of the metal layers 20 in the samples 1 to 3.

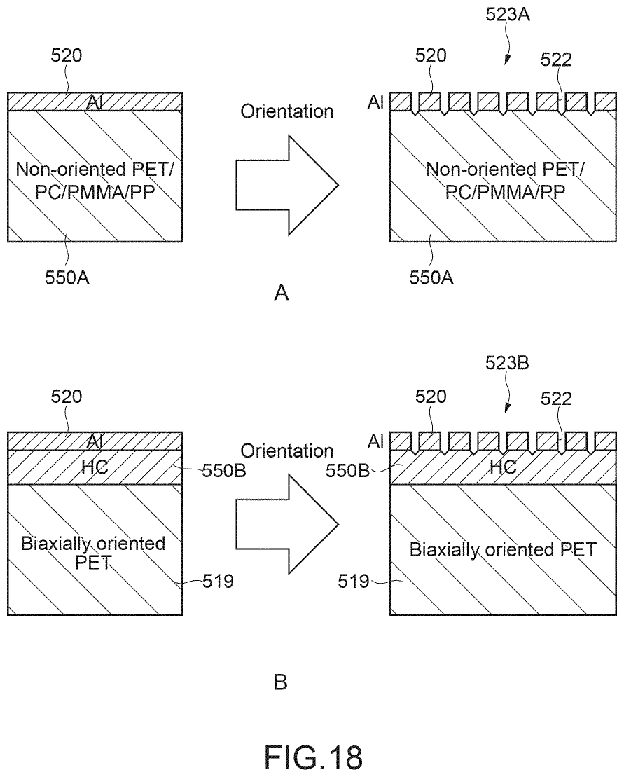

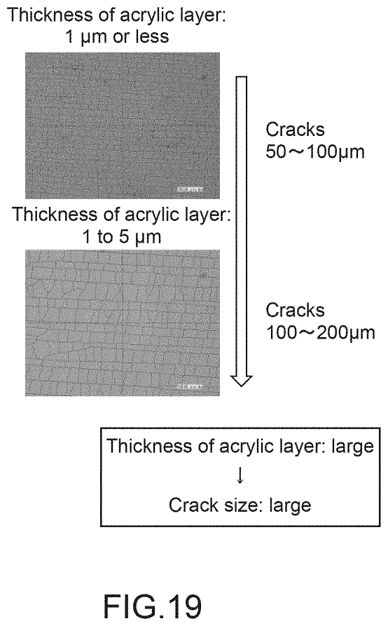

Here, in each of the decorative films 12 as which the samples 1 to 4 were prepared, the base film 19, a support layer, and the metal layer 20 were laminated in this order. The support layer is formed for a purpose of securing close-contact performance with respect to the metal layer 20, and has a function to induce cracking in the metal layer 20 in an orientation step. Details thereof are described below with reference to FIG. 18 and FIG. 19.

First, a method for analyzing an atomic composition in the thickness direction of the metal layer 20 is described. FIG. 13, which is a graph for description of the method, shows an example of an X-ray photoelectron spectroscopy (XPS) analysis of a narrow-scan spectrum (angular resolution capability) in Al2p.

In this embodiment, in order to analyze the composition distribution in the thickness direction of the metal layer 20, insides of the samples were exposed by surface etching, specifically, by irradiation with Ar ions, and then surface composition analyses were sequentially performed. Normally, XPS quantification is performed on the basis of a photoelectron peak area. The peak area is proportionate to an atomic percentage and a sensitivity of highlighted atoms. Thus, a quotient obtained by division of a peak area A by an RSF (Relative Sensitivity Factor) is a value proportionate to the atomic percentage. Therefore, by the following equation (1), relative quantification in which a sum of quantitative values of an element to be measured is obtained to be 100 atomic % can be performed.

[Math. 1]

Ci=Ai/RSFi/ΣAj/RSFi×100 (1)

Ci: quantitative value of element i (atm %)

Ai: peak area of element i

RSFi: relative sensitivity factor of element i

A position of a photoelectron peak shifts in accordance with differences in bonding states of the elements, and hence bond energy of electrons in the Al2p orbital in a state of the aluminum and bond energy of the same in a state of the aluminum oxide are different from each other. Thus, as indicated by measured values and a spectral waveform in FIG. 3, their peak positions are different from each other. Note that, the spectral waveform represents results of fitting of the measured values.

This spectral waveform is decomposed into a linear sum of an ideal waveform to be measured only from the aluminum and an ideal waveform to be measured only from the aluminum oxygen. Then, peak areas of these waveforms are substituted into the equation (1). With this, both a percentage of the aluminum and a percentage of the aluminum oxide in the metal layer 20 are quantified. Note that, a position at which a percentage of a carbon content is half of a percentage of a carbon content in an organic layer (support layer) under the metal layer 20 is set as a position of the deposition start surface of the metal layer 20 Note that, also when the support layer is not formed, a position of the deposition start surface can be similarly estimated with respect to the base film 19 as the organic layer.

The position in the thickness direction of the metal layer 20 can be calculated, for example, as follows. Specifically, the thickness of the metal layer 20 is measured in advance by a cross-sectional TEM (Transmission Electron Microscope). A time period of the irradiation with the Ar ions in single etching is fixed, and the composition analysis by the XPS is performed each time the etching is performed. Then, from how many times the etching is performed until the percentage of the carbon content is reduced to half of the percentage of the carbon content in the organic layer under the metal layer 20 (from the number of times of the etching to the deposition start surface), an etching depth per the number of times of the etching is calculated (thickness of metal layer 20/number of times of etching). With this, positions in the thickness direction of the surfaces that are subjected to the composition analyses can be easily calculated.

Generally, in many cases, metals and their oxides are different from each other in etching rate. When the aluminum and the aluminum oxide are different from each other in percentage, their etching depths per irradiation time period differ from each other. By calculating an average etching rate with respect to the entirety of the metal layer 20 as described above, for example, the difference in the etching rate can be ignored, which facilitate the composition analyses in the thickness direction. As a matter of course, other methods such as a method including measuring the thickness each time the etching is performed may be carried out.

With regard to the sample 1, with focus on a percentage of a carbon content in FIG. 10, it is understood that the position of the deposition start surface is approximately 125 nm, that is, the thickness of the metal layer 20 is approximately 125 nm. As shown in FIG. 9, the oxygen introducing mechanism 220 is arranged on the downstream side. An average percentage of the aluminum in a near region of from 0 nm to approximately 20 nm on the deposition-start surface side is 35 atm %. An average percentage of the aluminum in a near region of from 0 nm to approximately 20 nm on the deposition-end surface side is 14 atm %. An average percentage of the aluminum in the entirety of the metal layer 20 is 30 atm %. By using the first surface 20a as the deposition end surface, the highly-designable metallic luster can be exhibited.

The sample 2 is prepared at a higher introduction rate (flow rate: sccm) of the oxygen than that of the sample 1. With focus on a percentage of a carbon content in FIG. 11, it is understood that the position of the deposition start surface is approximately 140 nm, that is, the thickness of the metal layer 20 is approximately 140 nm. As shown in FIG. 9, the oxygen introducing mechanism 220 is arranged on the downstream side. The average percentage of the aluminum in the near region of from 0 nm to approximately 20 nm on the deposition-start surface side is 38 atm %. The average percentage of the aluminum in the near region of from 0 nm to approximately 20 nm on the deposition-end surface side is 3 atm %. The average percentage of the aluminum in the entirety of the metal layer 20 is 24 atm %. By using the first surface 20a as the deposition end surface, the highly-designable metallic luster can be exhibited.

The sample 3 is prepared at a substantially equal introduction rate (flow rate: sccm) of the oxygen to that of the sample 2. Meanwhile, other deposition conditions such as a deposition rate are changed from those at the time of preparing the sample 2.

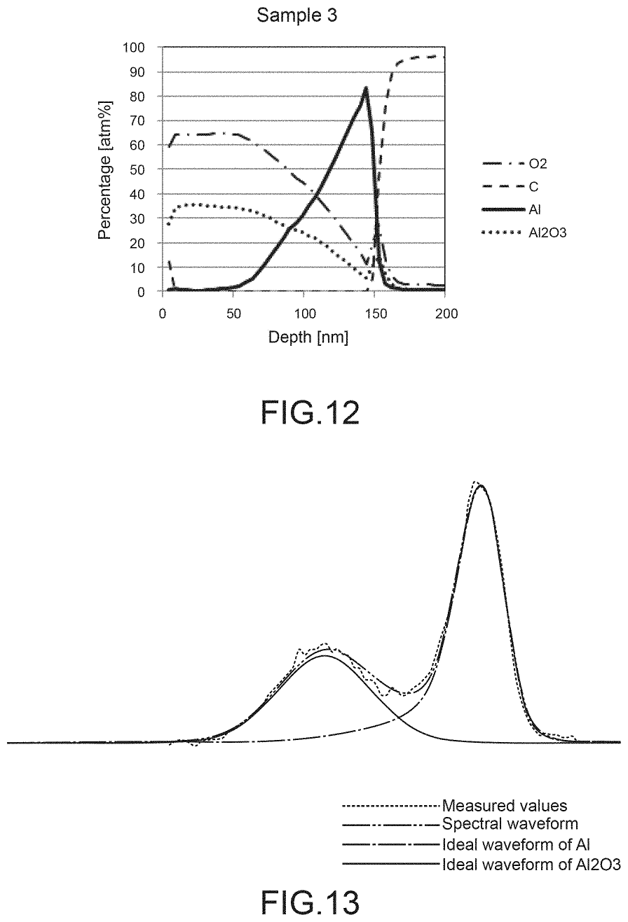

With focus on a percentage of a carbon content in FIG. 12, it is understood that the position of the deposition start surface is approximately 150 nm, that is, the thickness of the metal layer 20 is approximately 150 nm. As shown in FIG. 9, the oxygen introducing mechanism 220 is arranged on the downstream side. The average percentage of the aluminum in the near region of from 0 nm to approximately 20 nm on the deposition-start surface side is 59 atm %. The average percentage of the aluminum in the near region of from 0 nm to approximately 20 nm on the deposition-end surface side is 1 atm %. The average percentage of the aluminum in the entirety of the metal layer 20 is 24 atm %. By using the first surface 20a as the deposition end surface, the highly-designable metallic luster can be exhibited.

The sample 4 is prepared by arranging the oxygen introducing mechanism 220 on the upstream side. The average percentage of the aluminum in the near region of from 0 nm to approximately 20 nm on the deposition-start surface side is 2 atm %. The average percentage of the aluminum in the near region of from 0 nm to approximately 20 nm on the deposition-end surface side is 46 atm %. The average percentage of the aluminum in the entirety of the metal layer 20 is 25 atm %. By using the first surface 20a as the deposition start surface, the highly-designable metallic luster can be exhibited.

Next, the inventors measured the optical measurement by conducting the high-temperature and high-humidity tests with respect to the samples 1 to 4. Specifically, as shown in FIG. 9, the inventors measured whether or not transparentization occurred and variation in the reflectance in the visible-light band after storage at 75° C. and 90% RH for 8 D. With regard to the transparentization, it was determined that the transparentization occurred when a transmittance in the visible-light band was 5% or more, that the transparentization did not occur when the transmittance was less than 5%. Note that, in the table, the design surface of each of the samples 1 to 3 corresponds to the deposition start surface (measured through the transparent support layer and the base film 19), and the design surface of the sample 4 corresponds to the deposition end surface.

Note that, under an initial state in which the samples 1 to 4 were prepared, in each of the samples, the transmittance was 1% or less, that is, the transparentization did not occur. The reflectance of each of the design surfaces ranged from 75% to 85%. In other words, a significantly highly-designable metallic luster was exhibited.

With regard to the sample 1, the transmittance is 2% or less even after the storage for 8 days, that is, the transparentization is not observed. The variation in the reflectance of the design surface is less than 10%, that is, a high reflectance is maintained. Also with regard to the sample 2, the transmittance is 2% or less, that is, the transparentization is not observed. Meanwhile, in comparison with the sample 1, a decrease in the reflectance of the design surface was observed, and the variation in the reflectance occurred in a range up to 30%. This is probably due to a difference in the average percentage of the aluminum near the deposition end surface, which is described below.

With regard to the samples 3 and 4, the transmittance was 10% or more, and the transparentization was observed. In addition, the decrease in the reflectance of the design surface was conspicuously observed.

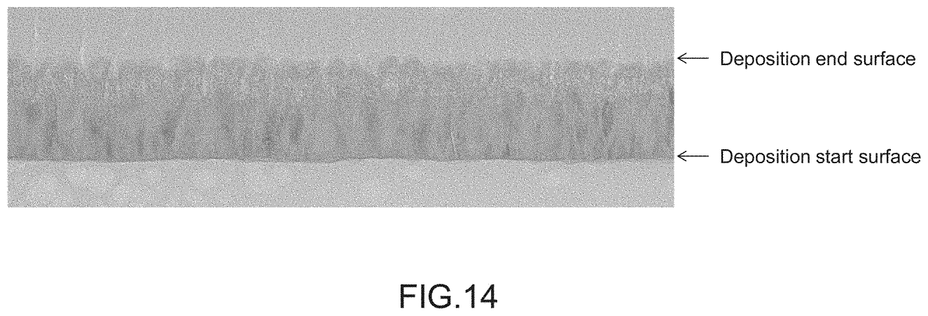

FIG. 14 is a photograph of a cross-sectional TEM image of the metal layer 20 in the sample 3 (inventors are ready to submit photographs at higher resolutions). In this embodiment, for example, a reactive gas such as the oxygen is introduced into a metal such as the aluminum, and a film to which the oxygen is added (metal layer 20) is formed. In this case, as can be seen from the deposition end surface in FIG. 14, it was understood that fineness of the film was lost, that is, a film density tended to decrease. As a result, probably, paths that allow intrusion of moisture and the like from outside are formed, and the oxidation of the metal layer 20 is promoted, whereby the transparentization is caused.

This probably does not occur only on the deposition-end surface side, but also in the deposition start surface on the side that is bonded to the base film 19. In other words, probably, the moisture and the like enter an inside through, for example, the base film 19, and the transparentization of the metal layer 20 is promoted.

In this context, the inventors have found that, under a state in which unreacted parts of the metal are left in the deposition start surface and the deposition end surface, specifically, in the near region in each of the first surface 20a and the second surface 20b, these unreacted parts of the metal are highly likely to transform into an oxide film to protect the metal in the inside from the corrosion. In other words, the inventors have found that, in each of the first near region 25 on the first surface 20a side, and the second near region 26 on the second surface 20b side, when a percentage of parts of the metal, which are uncombined with the oxygen, is equal to or more than a predetermined threshold, once these parts of the metal are oxidized, these parts are highly likely to exert a passivation function.

It was found that, as shown in FIG. 9, for example, in each of the near region up to approximately 20 nm from the deposition start surface, and the near region up to approximately 20 nm from the deposition end surface, when the percentage of the parts of the metal, which were uncombined with the oxygen, was 3 atm % or more, degradation of the metallic luster was successfully prevented, whereby the high designability was successfully maintained. In other words, the decreases in the reflectances, each of which was the same as or smaller than that of the sample 2, adequately fell within an acceptable range. Probably, metallic lusters of the samples 3 and 4 are liable to be degraded in 5 years or 10 years.

As a matter of course, the values for defining the near regions, and the threshold of the percentage of the unreacted parts of the metal material, which is necessary for forming the oxide film, are not limited respectively to the values of approximately 20 nm and 3 atm %, respectively. Conditions under which the variation in the optical characteristics during storage over a long time period falls within the acceptable range may be set as appropriate.

In the near region in each of the first surface 20a and the second surface 20b, by forming the metal layer 20 in a manner that the uncombined parts of the metal are contained at the percentage equal to or more than the threshold, the transparentization of the metal layer 20 over time is suppressed. As a result, the structure such as the casing component decorated with the decorative film 12 including the metal layer 20 is allowed to maintain its high designability even during storage in a high-temperature and high-humidity environment or even during the storage over a long time period.

Note that, the transparentization due to the oxidation of the metal layer 20 is a phenomenon that occurs mainly at the time when the aluminum is used. The transparentization may not be observed at times when other materials are used. However, also when the other metal materials are used, the film density similarly decreases by the addition of, for example, the oxygen, and the oxidation of the metal layer is similarly promoted. Thus, for example, a risk that the reflectance decreases due, for example, to variation in refractive index of the metal layer 20 cause the degradation of the metallic luster is fairly high. By forming metal layer 20 in a manner that the parts of the metal material, which are uncombined, for example, with the oxygen are secured in the near regions, the degradation of the metallic luster can be prevented. With this, the high designability is maintained.

The analysis described herein was performed on the film after the deposition, specifically, performed under a state in which the deposition end surface of the metal layer 20 was exposed. Thus, the composition analysis was successfully performed with this surface being subjected to Ar etching.

In a case of the state in which the decorative film 12 is bonded, for example, to the casing component, the composition analysis can be performed, for example, by exposing a metal surface by physically peeling off the resin layer or the like that is present on the deposition end surface. Even when the resin layer or the like cannot be physically peeled off, by processing analysis-target parts, for example, by chemical etching or with an FIB (Focused Ion Beam), and cutting off these parts, these parts can be analyzed by the XPS.

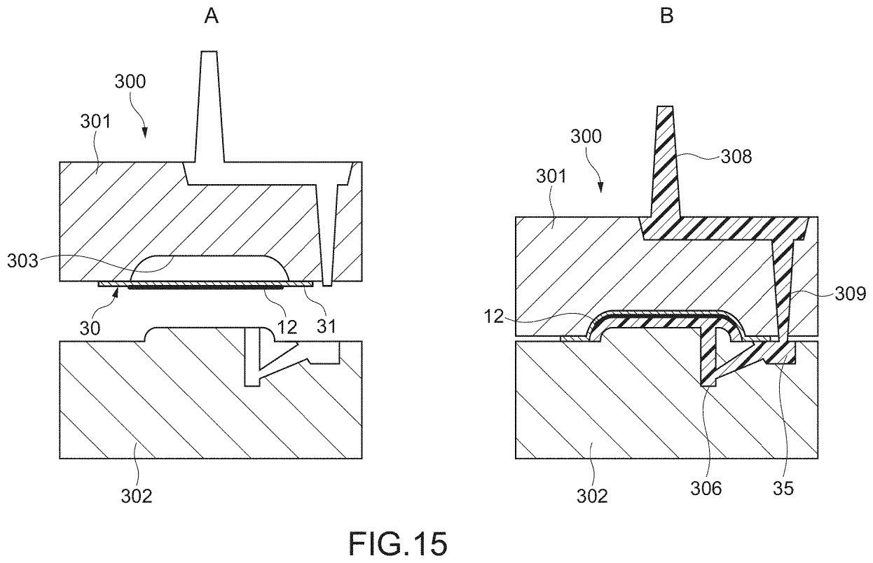

FIG. 15 is an explanatory schematic view illustrating an in-mold molding method. The in-mold molding is performed by a molding apparatus 300 including a cavity mold 301 and a core mold 302 as illustrated in FIG. 15. As illustrated in A of FIG. 15, a recess portion 303 conforming to a shape of the casing portion 101 is formed in the cavity mold 301. A transfer film 30 is arranged in a manner of covering the recess portion 303. The transfer film 30 is formed by bonding the decorative film 12 illustrated in FIG. 2 to a carrier film 31. The transfer film 30 is fed from an outside of the molding apparatus 300, for example, by the roll-to-roll system.

As illustrated in B of FIG. 15, the cavity mold 301 and the core mold 302 are clamped to each other, and a molding resin 35 is injected into the recess portion 303 through a gate portion 306 formed in the core mold 302. In the cavity mold 301, a sprue portion 308 through which the molding resin 35 is supplied, and a runner portion 309 that is coupled thereto are formed. By clamping the cavity mold 301 and the core mold 302 to each other, the runner portion 309 and the gate portion 306 are coupled to each other. With this, the molding resin 35 supplied to the sprue portion 308 is injected into the recess portion 303. Note that, the configuration for injecting the molding resin 35 is not limited.

As the molding resin 35, for example, general-purpose resins such as an ABS (acrylonitrile butadiene styrene) resin, a PC resin, engineering plastic such as a mixed resin of the ABS and the PC, and the like are used. The molding resin 35 is not limited thereto, and a material or a color (transparence) of the molding resin 35 may be selected as appropriate such that a desired casing portion (casing component) is obtained.

The molding resin 35 is injected in a state of being molten at high temperature into the recess portion 303. The molding resin 35 is injected in a manner of pressing an inner surface of the recess portion 303. At this time, the transfer film 30 arranged over the recess portion 303 is pressed and deformed by the molding resin 35. The heat of the molding resin 35 melts the adhesive layer 18 formed on the transfer film 30 to cause the decorative film 12 to be bonded to a surface of the molding resin 35.

After the molding resin 35 is injected, the cavity mold 301 and the core mold 302 are cooled, and then unclamped. The molding resin 35 to which the decorative film 12 is transferred has adhered to the core mold 302. By taking out the molding resin 35, the casing portion 101 including the metal decorative portion 10 formed in the predetermined region is produced. Note that, at the time of the unclamping, the carrier film 31 is peeled off.

Employment of the in-mold molding method facilitates positioning of the decorative film 12, thereby facilitating the formation of the metal decorative portion 10. In addition, a degree of freedom in designing the shape of the casing portion 101 is high, and hence the casing portion 101 to be produced is allowed to have various shapes.

Note that, the antenna unit 15 to be housed in the casing portion 101 may be attached by the in-mold molding method at the time of molding the casing portion 101. Alternatively, after the casing portion 101 is molded, the antenna unit 15 may be applied to the inside of the casing portion 101. Still alternatively, the antenna unit 15 may be built in the casing.

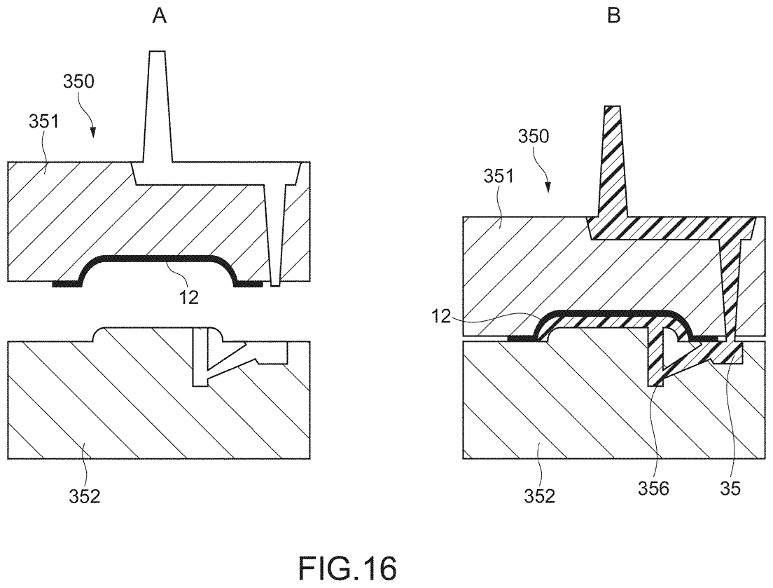

FIG. 16 is an explanatory schematic view illustrating an insert molding method. In the insert molding, the decorative film 12 is arranged as an insert film in a cavity mold 351 of a molding apparatus 350. Then, as illustrated in B of FIG. 16, the cavity mold 351 and a core mold 352 are clamped to each other, and the molding resin 35 is injected into the cavity mold 351 through a gate portion 356. With this, the casing portion 101 is formed integrally with the decorative film 12. Employment of the insert molding method also facilitates the formation of the metal decorative portion 10. In addition, the casing portion 101 to be produced is allowed to have various shapes. Note that, configurations of the molding apparatuses that perform the in-mold molding and the insert molding are not limited.

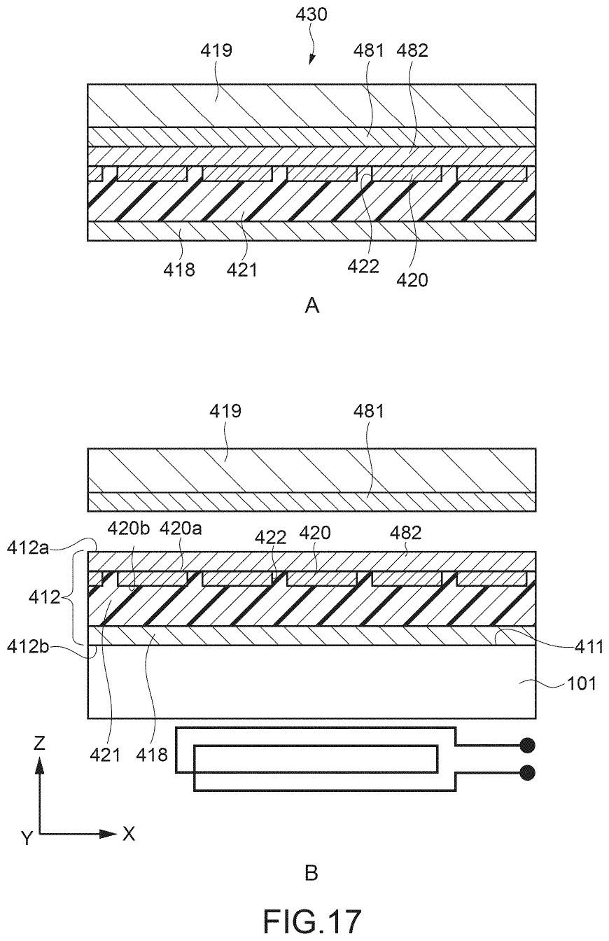

FIG. 17 is a schematic view illustrating a configuration example of a transfer film including a base film and a metal layer. This transfer film 430 includes a base film 419, a peel-off layer 481, a hard coating layer 482, a metal layer 420, a sealing resin 421, and an adhesive layer 418. The peel-off layer 481 and the hard coating layer 482 are formed in this order on the base film 419.

Thus, the metal layer 420 is formed on the base film 419 on which the peel-off layer 481 and the hard coating layer 482 are formed. Then, by orienting the base film 419, fine cracks 422 are formed in the metal layer 420.

As illustrated in B of FIG. 17, at a time when the casing portion 101 is formed by the in-mold molding method, the base film 419 and the peel-off layer 481 are peeled off, and a decorative portion 412 including the metal layer 420 is bonded to a decorated region 411. In such a way, the base film 419 may be used as a carrier film. Note that, the base film 419 on which the removed layer 481 is formed can be regarded as the base film according to the present technology. In addition, it can also be said that the decorative portion 412 peeled off from the base film 419 is the decorative film.

Note that, in the example illustrated in FIG. 17, a deposition start surface of the metal layer 420 corresponds to a first surface 420a on a design surface 412a side, and a deposition end surface of the same corresponds to a second surface 420b on an opposite side. Instead of this configuration, the transfer film may be prepared such that the deposition start surface corresponds to the second surface, and that the deposition end surface corresponds to the first surface.

By a hot stamping method with use of the transfer films 30 and 430 illustrated in FIG. 15 and FIG. 16, the casing portion 101 including the decorated region 11 to which the decorative film (decorative portion) 12 including the metal layer 20 has been transferred may be formed. Alternatively, the decorative film 12 may be bonded to the casing portion 101 by arbitrary methods such as applying. Still alternatively, vacuum molding, air-pressure molding, or the like may be employed.

As described hereinabove, in the casing portion 101 (casing component) being the structure according to this embodiment, the oxygen is added to vary in the addition concentration in the thickness direction of the single-layered metal layer 20. With this, the above-described metal layer 20 can be made, for example, of the aluminum or the like, which has a high reflectance. Further, by adjusting the addition concentration in the thickness direction, adjustment of the reflectance of the first surface 20a on the design surface 12a side also can be performed. As a result, the casing portion 101 can be formed to have the high designability, and to be capable of allowing radio waves to be transmitted therethrough despite having the metallic external appearance.

The metal material to which the present technology is applicable is not limited to the aluminum, and other metal materials such as sliver (Ag) may be used. Also in this case, by adding oxygen, the fine cracks 22 can be properly formed at the orientation percentage of 2% or less, and the metal layer 20 having the reflectance of 70% or more can be formed.

Alternatively, the aluminum, titanium, chromium, and an alloy containing at least one of these elements may be used as the metal material. These metals, which are what is called valve metals, are capable of exerting the above-described effect of the oxide film that prevents the oxidation. As a result, the high designability can be maintained for a long time period.

The element to be added is not limited to the oxygen, and, for example, nitrogen (N) may be added. Specifically, instead of the oxygen introducing mechanism 220 illustrated in FIG. 5, a nitrogen introducing mechanism may be arranged to blow the nitrogen as an introduced gas. More specifically, it is appropriate to set a supply rate as appropriate within a range from an addition rate at which a surface of a metal film after the orientation step enters an insulating state to an addition rate at which the metal layer is nitrided. By varying an addition concentration of the nitrogen in a film-thickness direction, the high designability can be exhibited. Further, by setting a percentage of parts of the metal, which are uncombined with the nitrogen, in the near region in each of the first surface and the second surface equal to or more than a predetermined threshold, progress of the nitridation can be prevented. Note that, other elements may be added.

If a thin film having island structures of In or Sn is used as the metal film that allows radio waves to be transmitted therethrough, a value of its reflectance is as small as approximately 50% to 60%. This is due to an optical constant of the material, and hence it is significantly difficult to achieve the reflectance of 70% or more as in the luster film 23 according to this embodiment. In addition, In is a rare metal, and hence a material cost increases.

Further, also at a time of forming the cracks in a film of a metal such as nickel or copper by performing post-baking by electroless plating, it is difficult to achieve the reflectance of 70% or more. Although it is conceived to exhibit a radio-wave permeability by increasing a sheet resistivity by alloying silicon and a metal with each other, also at this time, it is difficult to achieve the reflectance of 70% or more.

Still further, in this embodiment, since the film of the metal material is formed by the vacuum deposition, the materials such as the Al and Ti, which are difficult to deposit on a resin by wet plating such as the electroless plating, can be used. Thus, a range of options of usable metal materials is significantly wide, and hence metal materials each having a high reflectance can be used. Further, since the fine cracks 22 are formed by the biaxial orientation, the metal layer 20 can be formed with excellent close-contact performance by the vacuum deposition. As a result, at the time of the in-mold molding, or at the time of the insert molding, the casing portion 101 can be properly molded without, for example, causing the metal layer 20 to flow off. In addition, durability of the metal decorative portion 10 itself also can be increased.

Yet further, the luster film 23 can be formed only with the metal single-layered film. Thus, a simple deposition process with use of a simple deposition-source configuration can be used, and hence, for example, an apparatus cost can be suppressed. Note that, the method of forming the metal layer to which the oxygen or the nitrogen is added is not limited to the case of blowing the gas toward the film transport mechanism 201. For example, the oxygen or the like may be contained in the metal material in the crucible.

The present technology is applicable to almost all electronic apparatuses that house, for example, their built-in antennas therein. Specifically, as examples of such electronic apparatuses, there may be mentioned electronic apparatuses such as a feature phone, a smartphone, a personal computer, a gaming device, a digital camera, an audio device, a TV, a projector, a car navigation system, a GPS terminal, a digital camera, and a wearable information device (of eyeglass type or wristband type), operating devices that operate these devices via, for example, wireless communication, such as a remote control, a mouse, and a touch pen, in-vehicle electronic apparatuses such as an on-board radar system and an on-board antenna, and various other ones. In addition, the present technology is applicable also to IoT devices connected, for example, to the Internet.

Further, the present technology is not limited to the casing components for, for example, the electronic apparatuses, and applicable also to vehicles and constructions. Specifically, the structure according to the present technology, which includes the decorative portion and which includes the member including the decorated region to which the decorative portion is bonded, may be used as an entirety or a part of the vehicles and the constructions. With this, the vehicles and the constructions can have, for example, a wall surface capable of allowing radio waves to be transmitted therethrough despite having a metallic external appearance. As a result, significantly high designability can be exhibited. Note that, examples of the vehicles include arbitrary vehicles such as an automobile, a bus, and a train. Examples of the constructions include arbitrary constructions such as a house, an apartment building, a facility, and a bridge.

### Other Embodiments

The present technology is not limited to the embodiment described hereinabove, and various other embodiments may be carried out.

FIG. 18 is a cross-sectional view illustrating a configuration example of a luster film according to another embodiment. In this luster film 523, a support layer 550 having a tensile fracture strength lower than that of a metal layer 520 is provided as a layer that supports the metal layer 520. With this, an orientation percentage necessary for forming fine cracks 522 was successfully reduced. Specifically, the fine cracks 522 can be formed at an orientation percentage lower than an orientation percentage necessary for fracturing the metal layer 520 itself. This is probably because, as illustrated in A and B of FIG. 18, the metal layer 520 fractures along with fracturing of surfaces of support layers 550A and B each having the low tensile-fracture strength.

As illustrated in A of FIG. 18, a base film having the low tensile-fracture strength may be used as the support layer 550A. Specifically, biaxially oriented PET has a tensile fracture strength of from approximately 200 to approximately 250 MPa, which is higher than a tensile fracture strength of the aluminum layer 520 in many cases.

Meanwhile, tensile fracture strengths of non-oriented PET, PC, PMMA, and PP are as follows.

Non-oriented PET: Approximately 70 MPa

PC: From approximately 69 to approximately 72 MPa

PMMA: Approximately 80 MPa

PP: From approximately 30 to approximately 72 MPa

Thus, by using the base films made of these materials as the support layer 550A, the fine cracks 522 can be properly formed at the low orientation percentage. Note that, selection of the non-vinyl-chloride-based materials as that of the support layer 550A is advantageous in preventing the corrosion of the metal.

As illustrated in B of FIG. 18, a coating layer may be formed as the support layer 550B on a base film 519. Specifically, a hard coating layer, which is easily formed by performing coating with the acrylic resin or the like, can be formed as the support layer 550B.

By forming the coating layer having a low tensile-fracture strength between the base film 519 and the metal layer 520 each having the high tensile-fracture strength, even while maintaining a high durability of a luster film 523B, the fine cracks 522 can be formed at the low orientation percentage. Further, there are advantages, for example, in a case where the PET needs to be used in a producing step. Note that, the fractures of the surfaces of the base film and the hard coating layer that function as the support layer 550A and B illustrated in A and B of FIG. 18 are each as markedly small as a width of each of the fine cracks 522. Thus, the air entrainment or the like and the degradation of the designability or the like are not caused.

FIG. 19 is a view showing a relationship between a thickness of the coating layer formed as the support layer 550B, and a pitch (crack interval) of the fine cracks 522 to be formed in the metal layer 520. The relationship shown in FIG. 19 is that at a time when an acrylic layer is formed as the coating layer.

As shown in FIG. 19, when the thickness of the acrylic layer was 1 μm or less, the pitch of the fine cracks 522 was 50 μm to 100 μm. Meanwhile, when the thickness of the acrylic layer was set within a range of from 1 μm to 5 μm, the pitch of the fine cracks 522 ranged from 100 μm to 200 μm. In such a way, it was found that the larger the thickness of the acrylic layer became, the larger the pitch of the fine cracks 522 became. Thus, by controlling the thickness of the acrylic layer as appropriate, the pitch of the fine cracks 522 can be adjusted. Specifically, by setting the thickness of the acrylic layer to 0.1 μm or more and 10 μm or less, the thickness of the fine cracks 522 can be adjusted within a desired range. As a matter of course, the range is not limited thereto, and, for example, a specific optimum-numerical range may be set within the range of from 0.1 μm or more to 10 μm or less.

The orientation for forming the fine cracks is not limited to the biaxial orientation, and uniaxial orientation or tri- or more axial orientation may be performed. Alternatively, the biaxial orientation by the roll-to-roll system may be additionally performed on the base film 19 that has been taken up by the take-up roll 207 illustrated in FIG. 5. Still alternatively, the biaxial orientation may be performed at a timing between a timing after the vacuum deposition is performed and a timing before the base film 19 is taken up by the take-up roll 207.

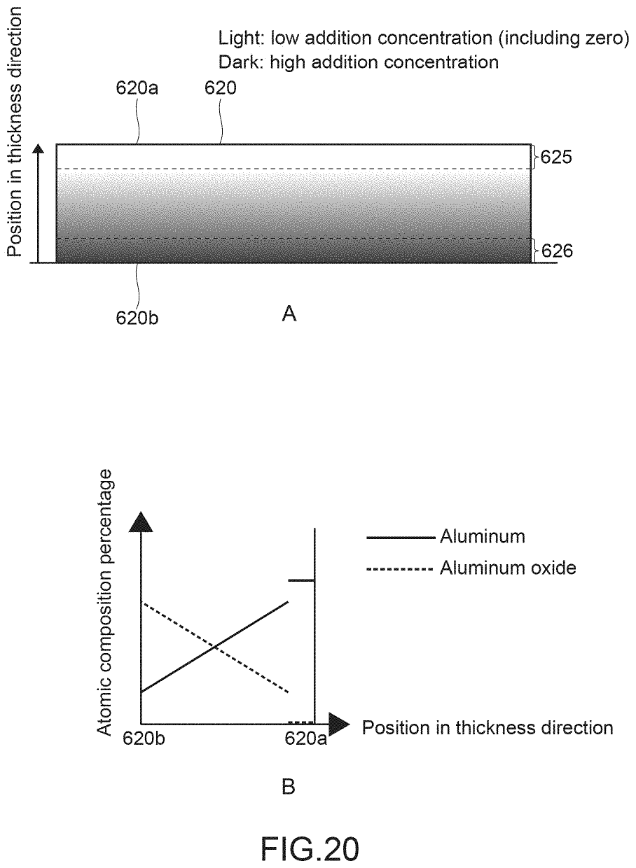

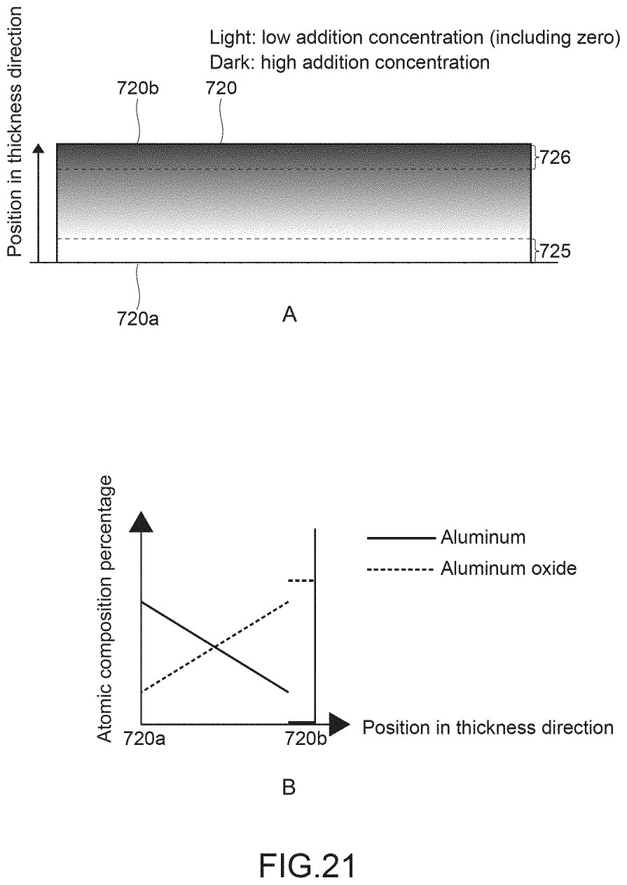

FIG. 20 and FIG. 21 are each an explanatory view showing another configuration example of the metal layer to which the predetermined element is added. Specifically, as illustrated in A and shown in B of FIG. 20, when a deposition end surface of a metal layer 620 corresponds to a first surface 620a of the same, a first near region 625 on the first surface 620a side may be formed as a region in which the predetermined element is not added. A second near region 626 on a second surface 620b side, which is the deposition start surface, corresponds to the high addition-concentration region.

Further, as shown in FIG. 21, when a deposition start surface of a metal layer 720 corresponds to a first surface 720a of the same, a first near region 725 on the first surface 720a side may be formed as the region in which the predetermined element is not added. A second near region 726 on a second surface 720b side, which is the deposition end surface, corresponds to the high addition-concentration region.

The metal layers 620 and 720 including the first near regions 625 and 725 can each be easily formed to have the addition concentration of zero by using, for example, the vacuum deposition apparatus of the batch type. Specifically, by restricting the introduction of the predetermined element at a predetermined timing before an end of the vacuum deposition of the metal material, an addition concentration in the near region in the deposition end surface can be reduced to zero (FIG. 20). Alternatively, by restricting the introduction of the predetermined element from a start of the vacuum deposition of the metal material to the predetermined timing, an addition concentration in the near region in the deposition start surface can be reduced to zero (FIG. 21).

When the vacuum deposition apparatus of the roll-to-roll type is used, a region into which the element does not flow is provided on the downstream side or the upstream side with respect to the deposition region by using the partition wall or the like. With this, the addition concentration in the near region in each of the deposition end surface and the deposition start surface can be reduced to zero. As a matter of course, other methods may be employed.

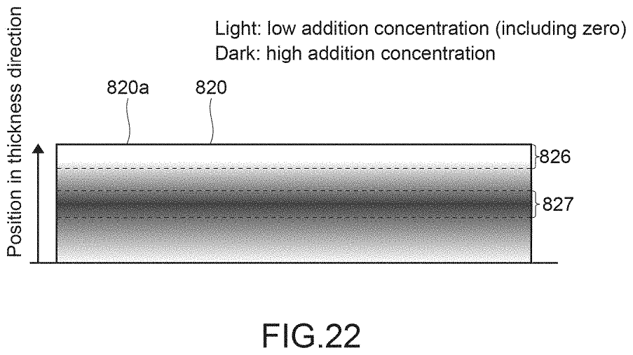

In the above description, the second near region on the second surface side is formed as the high addition-concentration region having the relatively-high addition concentration of the predetermined element. Instead, for example, as illustrated in FIG. 22, a central region 827 in a thickness direction of a metal layer 820 may be set as the high addition-concentration region. Specifically, on a first surface 820a side of the metal layer 820, by setting at least a part region out of a first near region 825 as the high addition-concentration region, the fine cracks can be easily formed.

A method of forming the high addition-concentration region at a predetermined position in a film may include, for example, increasing the introduction rate of the predetermined element at a predetermined timing in the vacuum deposition apparatus of the batch type. Specifically, by increasing the introduction rate at a middle timing during a deposition time period, the central region 827 in the film can be formed as the high addition-concentration region. At the time when the vacuum deposition apparatus of the roll-to-roll type is used, the position of the high addition-concentration region can be adjusted, for example, by controlling the position of the introducing mechanism that introduces the predetermined element. Other methods may be employed.

Note that, in order that the first surface of the metal layer has a desired reflectance, a configuration in which not the first near region near the first surface but another region having a somewhat-high addition concentration is intentionally formed as the low addition-concentration region may be employed.

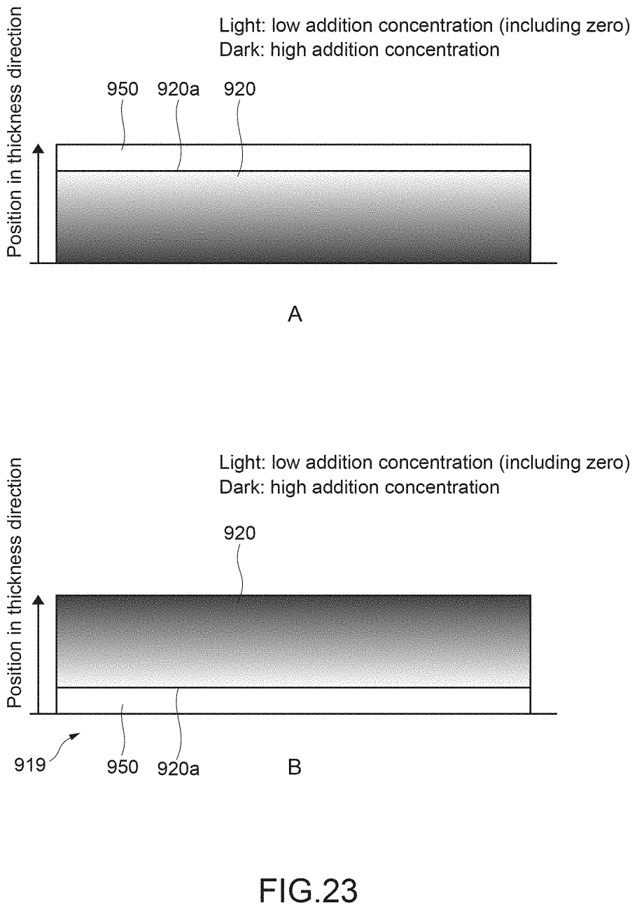

FIG. 23 is a schematic view illustrating another configuration example of the decorative film. Another metal layer 950 may be laminated additionally on a metal layer 920 according to the present technology, which is formed to vary in the addition concentration in its thickness direction. Specifically, as illustrated in A of FIG. 23, the other metal layer 950, to which the predetermined element has not been added, is laminated on the deposition end surface corresponding to a first surface 920a of the metal layer 920. Alternatively, as illustrated in B of FIG. 23, the other metal layer 950, to which the predetermined element has not been added, may be formed between the deposition start surface corresponding to the first surface 920a of the metal layer 920 and a base film 919. More specifically, by performing the deposition step a plurality of times, the configuration including the other metal layer 950 can be easily provided.

The configuration including the other metal layer 950 is also included in the configuration of the decorative portion according to the present technology, and the significantly highly-designable metallic luster can be exhibited. Note that, still another metal layer may be formed on a second surface side of the metal layer 950.

At least two of the features described hereinabove of the present technology may be combined with each other. In other words, various features described respectively in the embodiments may be arbitrarily combined with each other regardless of these embodiments. Further, the various advantages described hereinabove are merely examples, and hence are not limited thereto. Thus, other advantages may be additionally obtained.

Note that, the present technology may also employ the following configurations.

(1) A structure, including:

a decorative portion including a single-layered metal layer that includes fine cracks and varies in addition concentration of a predetermined element in a thickness direction of the metal layer; and

a member including a decorated region to which the decorative portion is bonded.

(2) The structure according to (1), in which

the decorative portion has a design surface,

the metal layer has
a first surface on the design surface side, and
a second surface on a side opposite to a side of the first surface, and

a region near the first surface corresponds to a low addition-concentration region in which the addition concentration is relatively low.

(3) The structure according to (2), in which

the low addition-concentration region includes a region in which the addition concentration is zero.

(4) The structure according to (2) or (3), in which

in the metal layer, at least a part region out of the region near the first surface corresponds to a high addition-concentration region in which the addition concentration is relatively high.

(5) The structure according to any one of (2) to (4), in which

in the metal layer, the addition concentration decreases from the second surface toward the first surface.

(6) The structure according to any one of (2) to (5), in which

in the metal layer, in both the region near the first surface and a region near the second surface, a percentage of a metal that is uncombined with the predetermined element is equal to or more than a predetermined threshold.

(7) The structure according to (6), in which

in the metal layer, in both a region up to approximately 20 nm from the first surface and a region up to approximately 20 nm from the second surface, a percentage of a metal that is uncombined with the predetermined element is approximately 3 atm % or more.

(8) The structure according to any one of (1) to (7), in which

the predetermined element is oxygen or nitrogen.

(9) The structure according to any one of (1) to (8), in which

the metal layer is any of aluminum, titanium, chromium, and an alloy containing at least one of the aluminum, the titanium, or the chromium.

(10) The structure according to any one of (1) to (9), in which

the metal layer has a thickness of 50 nm or more and 300 nm or less.

(11) The structure according to any one of (1) to (10), in which

the fine cracks have a pitch within a range of 1 μm or more and 500 μm or less.

(12) The structure according to any one of (1) to (11), in which

the decorative portion includes a support layer
that has a tensile fracture strength lower than a tensile fracture strength of the metal layer, and
that supports the metal layer.
   (13) The structure according to any one of (1) to (12), in which

the decorative portion includes a fixing layer that fixes the fine cracks.

(14) The structure according to any one of (1) to (13), in which

the structure is formed as at least a part of a casing component, a vehicle, or a construction.

(15) A decorative film, including:

a base film; and

a single-layered metal layer that is formed with respect to the base film, includes fine cracks, and varies in addition concentration of a predetermined element in a thickness direction of the metal layer.

(16) A method for producing a structure, the method including:

forming a decorative film including a single-layered metal layer to which a predetermined element is added and in which fine cracks are formed,
the forming of the decorative film including
   forming, by deposition, the metal layer with respect to a base film in a manner that an addition concentration of the predetermined element varies in a thickness direction of the metal layer, and
   forming the fine cracks in the metal layer by orienting the base film;

forming a transfer film by bonding a carrier film to the decorative film; and

forming a molded component in a manner that the decorative film is transferred from the transfer film by an in-mold molding method, a hot stamping method, or a vacuum molding method.

(17) A method for producing a structure, the method including:

forming a transfer film including a single-layered metal layer to which a predetermined element is added and in which fine cracks are formed,
the forming of the transfer film including
   forming, by deposition, the metal layer with respect to a base film in a manner that an addition concentration of the predetermined element varies in a thickness direction of the metal layer, and
forming the fine cracks in the metal layer by orienting the base film; and

forming a molded component in a manner that the metal layer peeled off from the base film is transferred by an in-mold molding method, a hot stamping method, or a vacuum molding method.

(18) A method for producing a structure, the method including:

forming a decorative film including a single-layered metal layer to which a predetermined element is added and in which fine cracks are formed,
the forming of the decorative film including
   forming, by deposition, the metal layer with respect to a base film in a manner that an addition concentration of the predetermined element varies in a thickness direction of the metal layer, and
   forming the fine cracks in the metal layer by orienting the base film; and

forming a molded component integrally with the decorative film by an insert molding method.

(19) The method for producing the structure according to any one of (16) to (18), in which

the forming of the fine cracks includes biaxially orienting the base film at an orientation percentage of 2% or less in each axial direction.

(20) A method for producing a decorative film, the method including:

forming, with respect to a base film by deposition, a single-layered metal layer to which a predetermined element is added in a manner that an addition concentration of the predetermined element varies in a thickness direction of the metal layer; and

forming fine cracks in the metal layer by orienting the base film.

### REFERENCE SIGNS LIST

10 metal decorative portion
11, 411 decorated region
12 decorative film
12a, 412a design surface
19, 419, 519, 919 base film
20, 420, 520, 620, 720, 820, 920 metal layer
20a, 420a, 620a, 720a, 820a, 920a first surface
20b, 420b, 620b, 720b, 820b second surface
21, 421 sealing resin
22, 422, 522 fine cracks
25, 625, 725, 825 first near region
26, 626, 726 second near region
30, 430 transfer film
90 aluminum
100 mobile terminal
101 casing portion
200 vacuum deposition apparatus
250 axial orientation apparatus
300 molding apparatus
350 molding apparatus
412 decorative portion
550A, 550B support layer

What is claimed is:

1. A structure, comprising:
a decorative portion including a single-layered metal layer that includes fine cracks and varies in addition concentration of a predetermined element in a thickness direction of the metal layer; and
a member including a decorated region to which the decorative portion is bonded.

2. The structure according to claim 1, wherein
the decorative portion has a design surface,
the metal layer has
a first surface on the design surface side, and
a second surface on a side opposite to a side of the first surface, and
a region near the first surface corresponds to a low addition-concentration region in which the addition concentration is relatively low.

3. The structure according to claim 2, wherein
the low addition-concentration region includes a region in which the addition concentration is zero.

4. The structure according to claim 2, wherein
in the metal layer, at least a part region out of the region near the first surface corresponds to a high addition-concentration region in which the addition concentration is relatively high.

5. The structure according to claim 2, wherein
in the metal layer, the addition concentration decreases from the second surface toward the first surface.

6. The structure according to claim 2, wherein
in the metal layer, in both the region near the first surface and a region near the second surface, a percentage of a metal that is uncombined with the predetermined element is equal to or more than a predetermined threshold.

7. The structure according to claim 6, wherein
in the metal layer, in both a region up to approximately 20 nm from the first surface and a region up to approximately 20 nm from the second surface, a percentage of a metal that is uncombined with the predetermined element is approximately 3 atm % or more.

8. The structure according to claim 1, wherein
the predetermined element is oxygen or nitrogen.

9. The structure according to claim 1, wherein
the metal layer is any of aluminum, titanium, chromium, and an alloy containing at least one of the aluminum, the titanium, or the chromium.

10. The structure according to claim 1, wherein
the metal layer has a thickness of 50 nm or more and 300 nm or less.

11. The structure according to claim 1, wherein
the fine cracks have a pitch within a range of 1 μm or more and 500 μm or less.

12. The structure according to claim 1, wherein
the decorative portion includes a support layer
that has a tensile fracture strength lower than a tensile fracture strength of the metal layer, and
that supports the metal layer.

13. The structure according to claim 1, wherein
the decorative portion includes a fixing layer that fixes the fine cracks.

14. The structure according to claim 1, wherein
the structure is formed as at least a part of a casing component, a vehicle, or a construction.

15. A decorative film, comprising:
a base film; and
a single-layered metal layer that is formed with respect to the base film, includes fine cracks, and varies in addition concentration of a predetermined element in a thickness direction of the metal layer.

16. A method for producing a structure, the method comprising:
forming a decorative film including a single-layered metal layer to which a predetermined element is added and in which fine cracks are formed,
the forming of the decorative film including
forming, by deposition, the metal layer with respect to a base film in a manner that an addition concentration of the predetermined element varies in a thickness direction of the metal layer, and
forming the fine cracks in the metal layer by orienting the base film;
forming a transfer film by bonding a carrier film to the decorative film; and
forming a molded component in a manner that the decorative film is transferred from the transfer film by an in-mold molding method, a hot stamping method, or a vacuum molding method.

17. A method for producing a structure, the method comprising:
forming a transfer film including a single-layered metal layer to which a predetermined element is added and in which fine cracks are formed,
the forming of the transfer film including
forming, by deposition, the metal layer with respect to a base film in a manner that an addition concentration of the predetermined element varies in a thickness direction of the metal layer, and
forming the fine cracks in the metal layer by orienting the base film; and
forming a molded component in a manner that the metal layer peeled off from the base film is transferred by an in-mold molding method, a hot stamping method, or a vacuum molding method.

18. A method for producing a structure, the method comprising:
forming a decorative film including a single-layered metal layer to which a predetermined element is added and in which fine cracks are formed,
the forming of the decorative film including
forming, by deposition, the metal layer with respect to a base film in a manner that an addition concentration of the predetermined element varies in a thickness direction of the metal layer, and
forming the fine cracks in the metal layer by orienting the base film; and
forming a molded component integrally with the decorative film by an insert molding method.

19. The method for producing the structure according to claim 16, wherein
the forming of the fine cracks includes biaxially orienting the base film at an orientation percentage of 2% or less in each axial direction.

20. A method for producing a decorative film, the method comprising:
forming, with respect to a base film by deposition, a single-layered metal layer to which a predetermined element is added in a manner that an addition concentration of the predetermined element varies in a thickness direction of the metal layer; and
forming fine cracks in the metal layer by orienting the base film.
